(19) United States
(12) Patent Application Publication
(10) Pub. No.: US 2014/0042531 A1
(43) Pub. Date: Feb. 13, 2014

(54) SEMICONDUCTOR DEVICE AND METHOD FOR FABRICATING THE SAME

(71) Applicant: SAMSUNG ELECTRONICS CO., LTD., Suwon-si (KR)

(72) Inventors: Chan-Ho PARK, Seongnam-si (KR); Min-Kwon CHO, Hwaseong-si (KR); Takayuki GOMI, Seongnam-si (KR); Nam-Ki CHO, Goyang-si (KR); Won-Sang CHOI, Seoul (KR)

(73) Assignee: SAMSUNG ELECTRONICS CO., LTD., Suwon-si (KR)

(21) Appl. No.: 13/963,194

(22) Filed: Aug. 9, 2013

(30) Foreign Application Priority Data
Aug. 13, 2012 (KR) 10-2012-0088495

(51) Int. Cl. H01L 29/78

(52) U.S. Cl. CPC H01L 29/7813
USPC 257/330

(57) ABSTRACT

A semiconductor device includes a trench in a substrate, a gate filling a part of the trench, a tilted source on a side wall of the trench, the tilted source partially overlapping the gate, an interlayer insulating film on the substrate and filling the trench, and a contact hole penetrating parts of the interlayer insulating film and the substrate and contacting the tilted source, the contact hole having a tilted surface at an angle that is equal to or larger than 80 degrees and smaller than 90 degrees.

### CROSS-REFERENCE TO RELATED APPLICATIONS

The present application claims priority under 35 U.S.C. §119 to Korean Patent Application No. 10-2012-0088495, filed on Aug. 13, 2012, in the Korean Intellectual Property Office, and entitled: “Semiconductor Device and Method for Fabricating the Same,” which is incorporated by reference herein in its entirety.

### BACKGROUND

1. Field

Embodiments relate to a semiconductor device and a method for fabricating the same, and more particularly, to a high-voltage MOSFET having a trench gate structure and a method for fabricating the same.

2. Description of the Related Art

High-voltage semiconductor devices include, e.g., a metal oxide semiconductor field-effect transistor (MOSFET), a bipolar transistor, an insulated-gate bipolar transistor (IGBT), and the like. For example, a MOSFET may include a gate electrode formed in a trench of a substrate, a source formed on one side of the substrate, and a drain formed on the other side of the substrate. Due to this structure, a channel of the MOSFET is formed in a vertical direction.

### SUMMARY

Example embodiments provide a semiconductor device having stable threshold voltage and dielectric strength.

According to an aspect of embodiments, there is provided a semiconductor device including a trench in a substrate, a gate filling a part of the trench, a tilted source on a side wall of the trench, the tilted source partially overlapping the gate, an interlayer insulating film on the substrate and filling the trench, and a contact hole penetrating parts of the interlayer insulating film and the substrate and contacting the tilted source, the contact hole having a tilted surface at an angle that is equal to or larger than 80 degrees and smaller than 90 degrees.

A first depth from an upper surface of the interlayer insulating film to a bottom surface of the contact hole may be equal to or larger than a second depth from the upper surface of the interlayer insulating film to an upper surface of the gate.

An upper surface of the interlayer insulating film may be planarized.

The semiconductor device may further include a gate insulating film along an upper surface of the substrate and along a side wall and a bottom surface of the trench, the contact hole penetrating parts of the interlayer insulating film, the gate insulating film, and the substrate.

The semiconductor device may further include a first conduction type body region in the substrate adjacent the gate, the tilted source being in the body region and of a second conduction type that is different from the first conduction type.

The semiconductor device may further include a high-concentration body region of the first conduction type in the body region and in contact with a bottom surface of the contact hole.

The tilted source may be in contact with the tilted surface of the contact hole and is spaced apart from the high-concentration body region.

A third depth from an upper surface of the substrate to a bottom surface of the trench may be equal to or larger than a fourth depth from the upper surface of the substrate to a bottom of the body region.

A difference between the third depth and the fourth depth may be equal to or larger than about 0 and is equal to or smaller than about 0.5 μM.

A ratio between the third depth and the fourth depth may be equal to or larger than about 1 and equal to or smaller than about 1.5.

The substrate may be of the second conduction type, the substrate including an impurity pillar of the first conduction type in the substrate along a vertical direction below the body region.

According to an aspect of embodiments, there is provided a semiconductor device including a trench in a substrate, a gate insulating film along an upper surface of the substrate and along a side wall and a bottom surface of the trench, a gate on the gate insulating film and filling a part of the trench, a tilted source on a side wall of the trench, the tilted source partially overlapping the gate, an interlayer insulating film on the substrate and filling the trench, and a contact hole penetrating parts of the interlayer insulating film, the gate insulating film, and the substrate, the contact hole being in contact with the tilted source and having a tilted surface at an angle that is equal to or larger than 80 degrees and smaller than 90 degrees, wherein a first depth from an upper surface of the interlayer insulating film to a bottom surface of the contact hole is equal to or longer than a second depth from the upper surface of the interlayer insulating film to an upper surface of the gate.

The upper surface of the interlayer insulating film may be planarized.

The semiconductor device may further include a first conduction type body region in the substrate adjacent to the gate, the tilted source being in the body region and is of a second conduction type that is different from the first conduction type.

The semiconductor device may further include a high-concentration body region of the first conduction type in the body region and in contact with a bottom surface of the contact hole.

According to an aspect of embodiments, there is provided a semiconductor device including a trench in a substrate, a gate filling a part of the trench, a tilted source on a side wall of the trench, a bottom of the tilted source overlapping a portion of the gate and being non parallel with respect to a bottom of the substrate, an interlayer insulating film on the substrate and filling the trench, and a contact hole penetrating parts of the interlayer insulating film and the substrate and contacting the tilted source, the contact hole having a tilted surface at an angle that is equal to or larger than 80 degrees and smaller than 90 degrees.

A first depth from an upper surface of the interlayer insulating film to a bottom surface of the contact hole may be equal to or larger than a second depth from the upper surface of the interlayer insulating film to an upper surface of the gate.

The first depth may equal the second depth.

A third depth from an upper surface of the substrate to a bottom surface of the trench may be equal to or larger than a fourth depth from the upper surface of the substrate to a bottom of the body region.

The entire bottom of the tilted source may be non parallel with respect to the bottom of the substrate, the bottom of the tilted source extending from the tilted surface of the contact hole to the sidewall of the trench.

### BRIEF DESCRIPTION OF THE DRAWINGS

Features will become apparent to those of ordinary skill in the art by describing in detail exemplary embodiments with reference to the attached drawings, in which:

FIG. 1 illustrates a plan view of a semiconductor device according to a first embodiment;

FIG. 2 illustrates a cross-sectional view taken along line I-I of FIG. 1;

FIG. 3 illustrates an enlarged view of a region II in FIG. 2;

FIG. 4 illustrates an enlarged view of a region III in FIG. 2;

FIG. 5 illustrates a diagram of experimental results explaining effects of a semiconductor device according to a first embodiment;

FIG. 6 illustrates a cross-sectional view of a semiconductor device according to a second embodiment;

FIG. 7 illustrates a cross-sectional view of a semiconductor device according to a third embodiment;

FIG. 8 illustrates a cross-sectional view of a semiconductor device according to a fourth embodiment;

FIG. 9 illustrates an exemplary circuit diagram explaining a semiconductor system with a semiconductor device according to some embodiments;

FIG. 10 illustrates an exemplary block diagram of an electronic system including a semiconductor system according to some embodiments;

FIGS. 11 and 12 illustrate exemplary views of semiconductor systems including the semiconductor device according to some embodiments; and

FIGS. 13 to 17 illustrate views of intermediate stages in a method for fabricating a semiconductor device according to a first embodiment.

### DETAILED DESCRIPTION

Advantages and features of example embodiments and methods of accomplishing the same may be understood more readily by reference to the following detailed description of preferred embodiments and the accompanying drawings. The example embodiments may, however, be embodied in many different forms and should not be construed as being limited to the embodiments set forth herein. Rather, these embodiments are provided so that this disclosure will be thorough and complete and will fully convey the inventive concept to those skilled in the art, and the example embodiments will only be defined by the appended claims. Thus, in some embodiments, well-known methods, procedures, components, and circuitry have not been described in detail to avoid unnecessarily obscuring aspects of the example embodiments.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

The terminology used herein is for the purpose of describing particular embodiments only and is not intended to be limiting of the example embodiments. As used herein, the singular forms “a,” “an” and “the” are intended to include the plural forms as well, unless the context clearly indicates otherwise. It will be further understood that the terms “comprises,” “comprising,” “includes” and/or “comprising,” when used in this specification, specify the presence of the stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

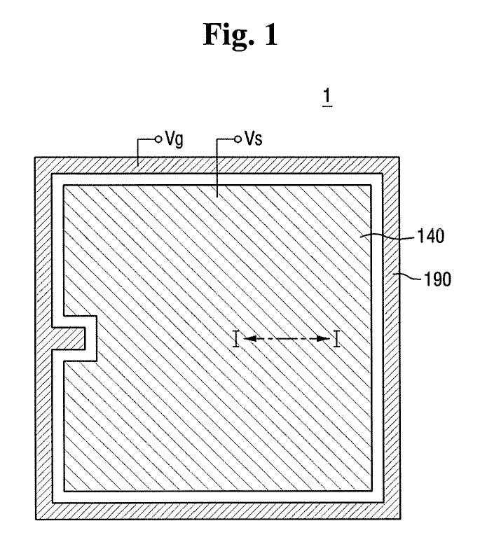

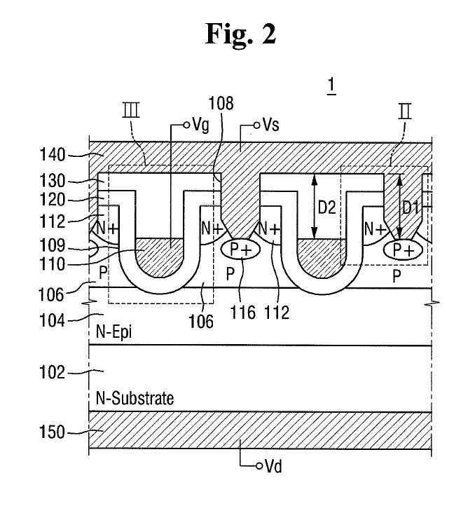

Hereinafter, preferred embodiments will be described with reference to the accompanying drawings. FIG. 1 is a plan view of a semiconductor device according to a first embodiment, and FIG. 2 is a cross-sectional view taken along line I-I of FIG. 1.

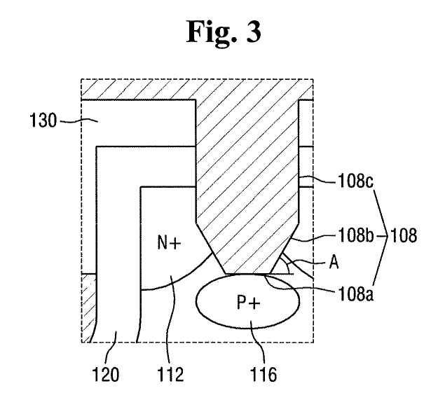

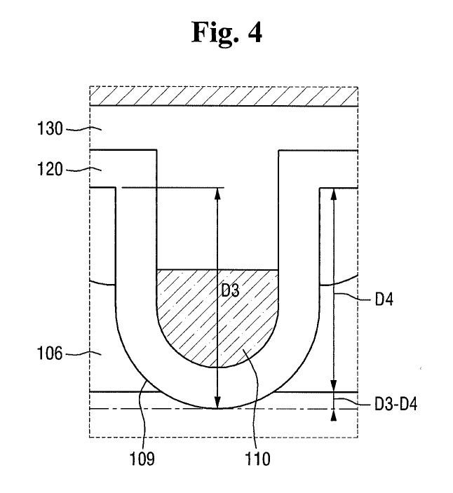

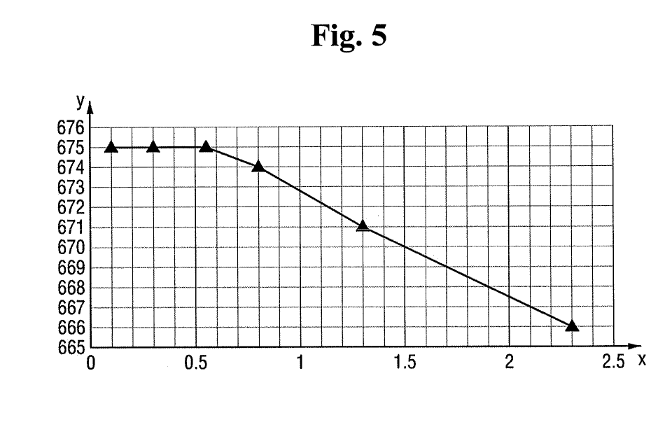

FIG. 3 is an enlarged view of a region II in FIG. 2, and FIG. 4 is an enlarged view of a region III in FIG. 2. FIG. 5 is a diagram of the result of experiment explaining effects of a semiconductor device according to a first embodiment.

First, referring to FIGS. 1 and 2, a semiconductor device according to a first embodiment may include substrates 102 and 104, a body region 106, a contact hole 108, a trench 109, a gate 110, a tilted source 112, a high-concentration body region 116, a source metal 140, a drain metal 150, and an interlayer insulating film 130.

The substrates 102 and 104 may include, but are not limited to, a base substrate 102 and an epi-layer 104. The base substrate 102 may be, e.g., a silicon substrate, a gallium-arsenide (GaAs) substrate, a silicon-germanium substrate, a ceramic substrate, a quartz substrate, or a glass substrate for display, or may be a SOI (Semiconductor on Insulator) substrate. Hereinafter, a silicon substrate will be exemplified. For example, the substrates 102 and 104 may be formed of only the base substrate 102 without the epi-layer 104. Further, the substrates 102 and 104 may be of, but are not limited to, a second conduction type (for example, N type).

The trench 109 is formed in the substrates 102 and 104, e.g., in an upper portion of the substrates 102 and 104. For example, the trench 109 may be formed within the epi-layer 104.

A gate insulating film 120 may be formed along an upper surface of the substrates 102 and 104, e.g., on an upper surface of the epi-layer 104, and along a side wall and a bottom surface of the trench 109. The gate insulating film 120 may include, e.g., at least one of a silicon oxide film, a silicon nitride film, a silicon oxynitride film, and a high-k material. The high-k material may include, e.g., at least one of HfO₂, ZrO₂, and Ta₂O₅.

The gate 110 may be formed so that the trench 109 is not fully filled with the gate 110, i.e., only a part of the trench 109 is filled with the gate 110. That is, the gate 110 may be in a recessed shape. The gate 110 may be formed, e.g., using polysilicon, but is not limited thereto. The gate 110 is electrically connected to the gate metal 190 (FIG. 1). A gate voltage Vg may be transferred to the gate 110 through the gate metal 190. As illustrated in FIG. 1, the gate metal 190 may be formed to surround the source metal 140, but is not limited thereto.

In a region between adjacent trenches 109, i.e., in a region between adjacent gates 110, a body region 106 may be formed, e.g., defined. The body region 106 may be of a first conduction type (for example, P type) that is different from the second conduction type (for example, N type) of the substrates 102 and 104.

The tilted source 112 is formed on a side wall, e.g., on an external side wall, of the trench 109, and overlaps a part of the gate 110. To be described later, the tilted source 112 may be formed by implanting impurities in the vertical direction and then implanting impurities at a tilted angle using the exposed gate 110. Accordingly, the tilted source 112 may not be in parallel to the substrates 102 and 104, but may be in a tilted shape against the substrates 102 and 104. For example, as illustrated in FIGS. 2-3, a bottom of the tilted source 112 facing the body region 106 may be non-parallel with respect to a bottom of the substrate 102, e.g., a tangent line to any point on the bottom of the tilted source 112 may be at an oblique angle with respect to the bottom of the substrate 102. The tilted source 112 may be of the second conduction type (for example, N type).

The interlayer insulating film 130 may be formed on the overall surface of the substrates 102 and 104. Specifically, the interlayer insulating film 130 may be formed to fill the trench 109 on the substrates 102 and 104 therewith, and may be formed on the gate insulating film 120 that is formed on the surface of the substrates 102 and 104. The interlayer insulating film 130 may be formed using a material having superior gap-filling ability. The interlayer insulating film 130 may be, but is not limited to, a silicon oxide film.

The contact hole 108 may be formed in a region between adjacent trenches 109, i.e., a region between adjacent gates 110. The contact hole 108 may be formed to penetrate parts of the interlayer insulating film 130, the gate insulating film 120, and the substrates 102 and 104.

The source metal 140 may be formed on an upper portion of the interlayer insulating film 130 and inside of the contact hole 108. The source metal 140 is electrically connected to the tilted source 112 and provides a source voltage Vs to the tilted source 112. As illustrated in FIG. 1, the source metal 140 may be formed in a plate shape, but is not limited thereto. The source metal 140 may include, e.g., at least one of aluminum, copper, tungsten, and titanium, but is not limited thereto.

Here, the surface of the interlayer insulating film 130 may be planarized. That is, since the surface of the interlayer insulating film 130 is not bent, e.g., completely flat, the surface of the source metal 140 that is formed on the surface of the interlayer insulating film 130 has a flat shape. Since the surface of the source metal 140 has a flat shape, e.g., the probability of occurrence of inferiority may be reduced when a conductor, e.g., wire bonding, for external connection is formed on the surface of the source metal 140.

The high-concentration body region 116 may be formed below the contact hole 108, and may be formed between adjacent tilted sources 112. The high-concentration body region 116 may be of the first conduction type (for example, P type), and may have higher concentration than the body region 106. The high-concentration body region 116 is to obtain good off-switch characteristics of the semiconductor device, e.g., MOSFET.

On the backside of the substrates 102 and 104, the drain metal 150 may be formed. However, forming the drain metal 150 is not limited thereto. The drain metal 150 may include, e.g., at least one of aluminum, copper, tungsten, and titanium, but is not limited thereto.

As illustrated in FIG. 2, a first depth D1 from an upper surface of the interlayer insulating film 130 to a bottom surface of the contact hole 108 may be equal to a second depth D2 from the upper surface of the interlayer insulating film 130 to an upper surface of the gate 110. Here, a case where the first depth D1 and the second depth D2 are equal to each other includes both a case where the first depth D1 and the second depth D2 are completely equal to each other and a case where the first depth D1 and the second depth D2 differ from each other within a specific margin range due to reasons in the processing.

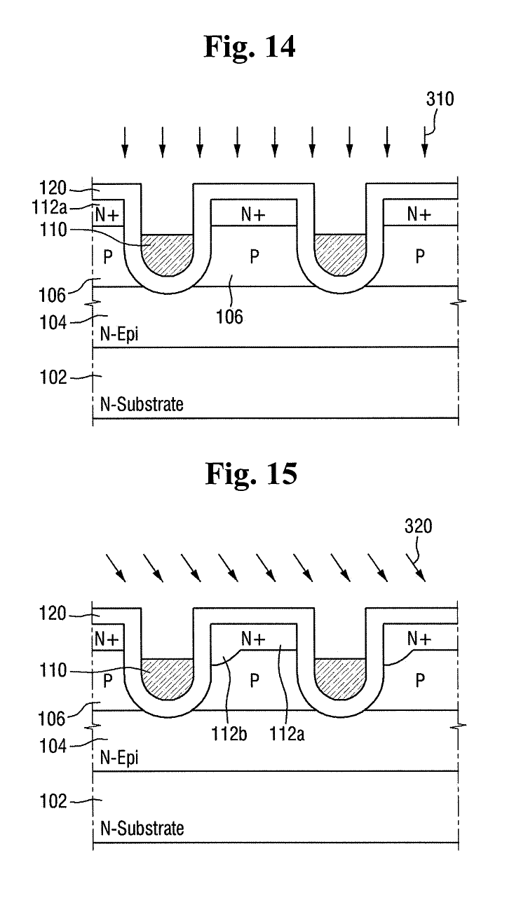

To be described later, the tilted source 112 may be formed by implanting impurities in the vertical direction and then implanting impurities at a tilted angle using the exposed gate 110 (see FIGS. 14 to 16). If the first depth D1 is shorter than the second depth D2, an unwanted second conduction type (N type) impurity region may exist below the bottom surface of the contact hole 108, i.e., in a region between the high-concentration body region 116 and the body region 106. Since the unwanted second conduction type impurity region, the body region 106, and the epi-layer 104 are of an N type, of a P type, and of an N type, respectively, an unwanted NPN parasitic transistor may be formed below the bottom surface of the contact hole 108. Such an NPN parasitic transistor may cause an abnormal operation.

Further, as illustrated in FIG. 3, the contact hole 108 may include a bottom surface 108a, a side wall 108c, and a tilted surface 108b connecting the bottom surface 108a and the side wall 108c to each other. The contact hole 108, e.g., the side wall 108c and the tilted surface 108b, contact, e.g., directly contact, the tilted source 112. Here, an angle A of the tilted surface 108b with respect to a bottom surface of the substrate 102 may be equal to or larger than about 80 degrees and smaller than about 90 degrees.

To be described in detail later, after the contact hole 108 is formed, the high-concentration body region 116 may be formed in the vicinity of, e.g., adjacent to, the bottom surface 108a of the contact hole 108 without using any separate mask. That is, the shape of the high-concentration body region 116 may be changed depending on the shape of the contact hole 108.

If the angle A of the tilted surface 108b of the contact hole 108 is smaller than 80 degrees, the high-concentration body region 116 may be formed to be diffused in the horizontal direction, i.e., a channel forming region may be doped with the first conduction type impurities for forming the high-concentration body region 116, thereby reducing stability characteristics of the semiconductor device. Accordingly, it is preferable that the angle A of the tilted surface 108b of the contact hole 108 is equal to or larger than 80 degrees.

Further, as illustrated in FIG. 4, a third depth D3 from the surface of the substrates 102 and 104, e.g., from an upper surface of the epi-layer 104, to a bottom surface of the trench 109 may be longer than a fourth depth D4 from the surface of the substrates 102 and 104, e.g., from the upper surface of the epi-layer 104, to a bottom of the body region 106.

In the case of a trench gate structure, electric field concentrates at a lower end portion of a trench, i.e., at a lower end portion of the trench 109, thereby decreasing the dielectric strength. Further, if the fourth depth D4 is longer than the third depth D3, the threshold voltage increases or open inferiority may occur. On the other hand, if the third depth D3 is formed to be too long to prevent the above-described inferiority, the increased concentration of electric field at the lower end portion of the trench 109 and the decreased drift region may be disadvantageous in forming the dielectric strength. Accordingly, it is necessary to optimize the relationship between the third depth D3 and the fourth depth D4.

Referring to FIG. 5, an x-axis represents a difference (D3−D4) between the third depth D3 and the fourth depth D4, and a y-axis represents the dielectric strength. As illustrated, if the difference (D3−D4) between the third depth D3 and the fourth depth D4 is implemented to be equal to or smaller than 0.5 μn, the change of the dielectric strength is insignificant. However, if the difference (D3−D4) exceeds 0.5 μm, the dielectric strength is rapidly decreased. Accordingly, it is preferable to implement the difference (D3−D4) to be larger than 0 and equal to or smaller than 0.5 μm. If it is assumed that the ratio between the third depth D3 and the fourth depth D4 is expressed as “p=D3/D4”, the ratio may be about 1<p≦1.5.

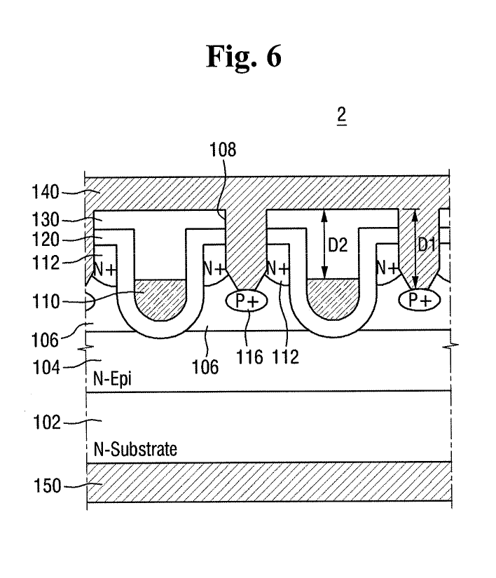

FIG. 6 illustrates a cross-sectional view of a semiconductor device according to a second embodiment. Hereinafter, explanation will be made to describe differences relative to the embodiments described in FIGS. 1 to 5.

Referring to FIG. 6, in a semiconductor device 2 according to the second embodiment, the first depth D1 from the surface of the interlayer insulating film 130 to the bottom surface of the contact hole 108 may be longer than the second depth D2 from the surface of the interlayer insulating film 130 to the upper surface of the gate 110. In this case, it is necessary to attend to whether the high-concentration body region 116 that is formed below the bottom surface 108a of the contact hole 108 exerts an influence on the channel.

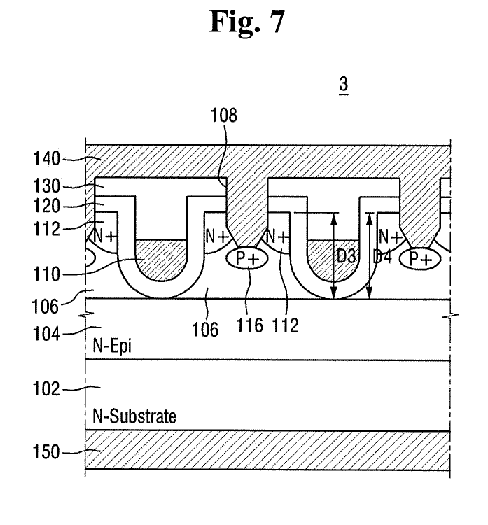

FIG. 7 illustrates a cross-sectional view of a semiconductor device according to a third embodiment. Hereinafter, explanation will be made to describe differences relative to the embodiments described in FIGS. 1 to 5.

Referring to FIG. 7, in a semiconductor device 3 according to the third embodiment, the third depth D3 from the surface of the substrates 102 and 104 to the bottom surface of the trench 109 may be equal to the fourth depth D4 from the surface of the substrates 102 and 104 to the body region 106. That is, the difference (D3−D4) may be 0. If it is assumed that the ratio between the third depth D3 and the fourth depth D4 is expressed as “p=D3/D4”, the ratio may be p=1. In this case, the threshold voltage is prevented from being increased, and the electric field is not concentrated at the lower end portion of the trench 109, thereby forming good dielectric strength.

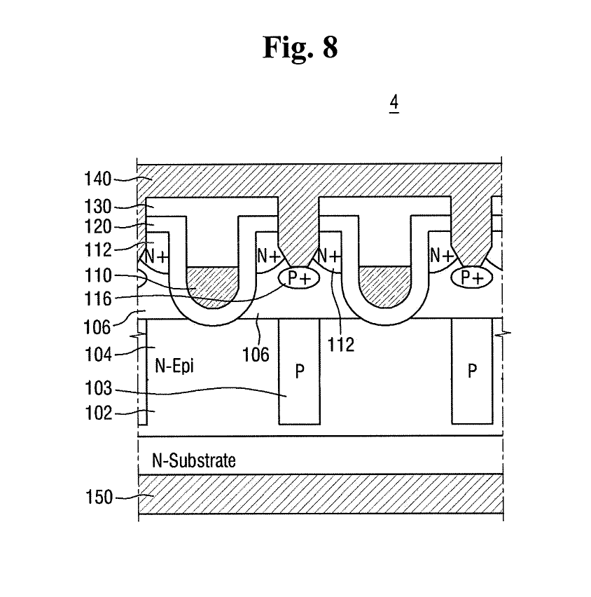

FIG. 8 illustrates a cross-sectional view of a semiconductor device according to a fourth embodiment. Hereinafter, explanation will be made to describe differences relative to the embodiments described in FIGS. 1 to 5.

Referring to FIG. 8, in a semiconductor device 4 according to the fourth embodiment, a first conduction type (for example, P type) impurity pillar 103 extends along a vertical direction below the body region 106 in the substrates 102 and 104, e.g., the impurity pillar 103 may extend within the epi-layer 104 from the bottom surface of the body region 106 toward the substrate 102. Since the substrates 102 and 104 are of a second conduction type, as illustrated, the semiconductor device 4 is shaped so that the first conduction type impurity pillar 103 and a second conduction type impurity region (of the epi-layer 104) are repeatedly arranged. That is, the semiconductor device 4 is shaped so that PN is repeatedly arranged. Here, a depletion layer is formed in a PN junction portion, and thus the depletion layer extends laterally in a narrow space between the PN. That is, a drift region is completely changed to the depletion layer at low voltage, and thus the electric field is not concentrated at a single portion. Accordingly, even if the drift region, through which current flows, is designed to have high concentration, high breakdown voltage can be secured. Therefore, forward characteristics of the semiconductor device 4 become superior.

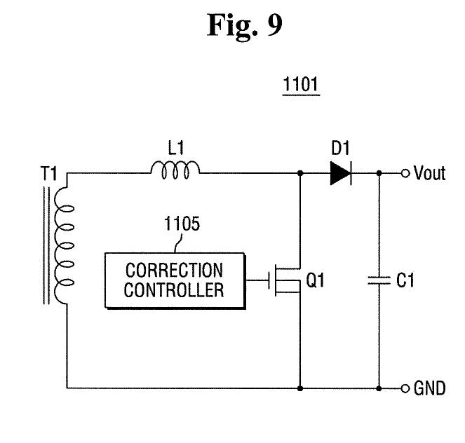

FIG. 9 illustrates an exemplary circuit diagram explaining a semiconductor system that includes a semiconductor device according to some embodiments. Here, the semiconductor system may be, e.g., a power supply device.

Referring to FIG. 9, a semiconductor system 1101 including the semiconductor device according to some embodiments may include a transformer T1, a choke coil L1, a rectifying diode D1, a smoothing capacitor C1, a switching transistor Q1, and a compensation controller 1105.

The choke coil L1 is connected to a secondary winding of the transformer T1 to compensate for distortion, e.g., current superposition or the like. The switching transistor Q1 switches an output of a voltage that passes through the choke coil L1 to an output terminal. The compensation controller 1105, i.e., a correction controller 1105, provides a control signal to the switching transistor Q1 to turn on/off the switching transistor Q1. The rectifying diode D1 rectifies voltage that is transferred through the choke coil L1. The smoothing capacitor C1 performs smoothing of the voltage that is rectified through the rectifying diode D1.

Here, the compensation controller 1105 may switch the switching transistor Q1 much faster than the frequency of an input voltage, and adjust the operating time of the switching transistor Q1 in proportion to the level of the input voltage. By doing so, the amount of current flowing through the choke coil L1 is controlled according to the switching period of the compensation controller 1105 to compensate for the power factor.

At least one of the semiconductor devices according to some embodiments as described above using FIGS. 1 to 8 may be used as the switching transistor Q1. Here, although it is exemplified that the semiconductor device according to some embodiments is used in a power supply device, the utilization of the semiconductor device is not limited thereto.

FIG. 10 illustrates an exemplary block diagram of an electronic system including a semiconductor system according to some embodiments.

Referring to FIG. 10, an electronic system 1100 may include a controller 1110, an input/output (I/O) device 1120, a memory device 1130, an interface 1140, a power supply device 1160, and a bus 1150. The controller 1110, the I/O device 1120, the memory device 1130, and/or the interface 1140 may be coupled to one another through the bus 1150. The bus 1150 corresponds to paths through which data is transferred.

The controller 1110 may include, e.g., at least one of a microprocessor, a digital signal processor, a microcontroller, and logic elements that can perform similar functions. The I/O device 1120 may include, e.g., a keypad, a keyboard, and a display device. The memory device 1130 may store data and/or commands. The interface 1140 may function to transfer the data to a communication network or to receive the data from the communication network. The interface 1140 may be of a wired or wireless type. For example, the interface 1140 may include an antenna or a wired/wireless transceiver. Although not illustrated, the electronic system 1100 may further include a high-speed DRAM and/or SRAM as an operating memory for improving the operation of the controller 1110. The field effect transistor according to embodiments may be provided inside the memory device 1130 or may be provided as a part of the controller 1110 and the I/O device 1120. The power supply device 1160 may convert and provide a power input from an outside to the respective constituent elements 1110, 1120, 1130, and 1140. One or more power supply devices 1160 may be provided in the electronic system 1100. The power supply device 1160 may be the device described using FIG. 9.

The electronic system 1100 may be applied, e.g., to a PDA (Personal Digital Assistant), a portable computer, a web tablet, a wireless phone, a mobile phone, a digital music player, a memory card, or all electronic devices that can transmit and/or receive information in wireless environments.

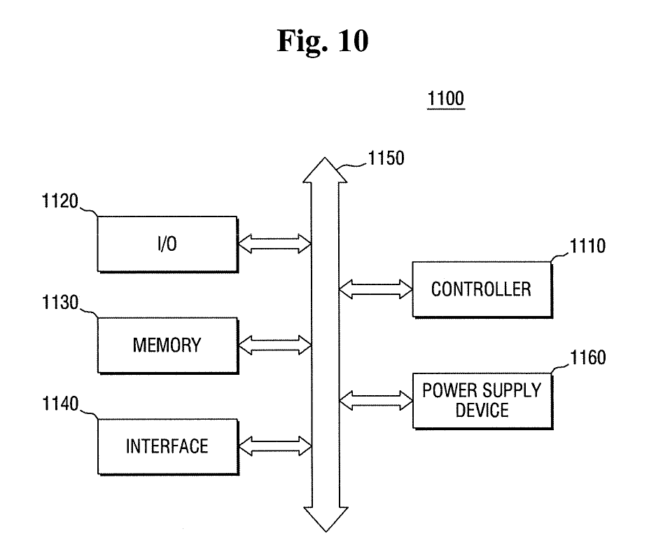

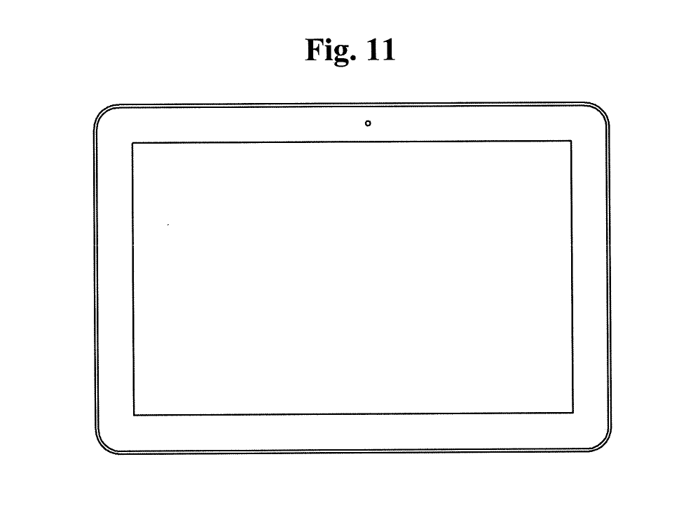

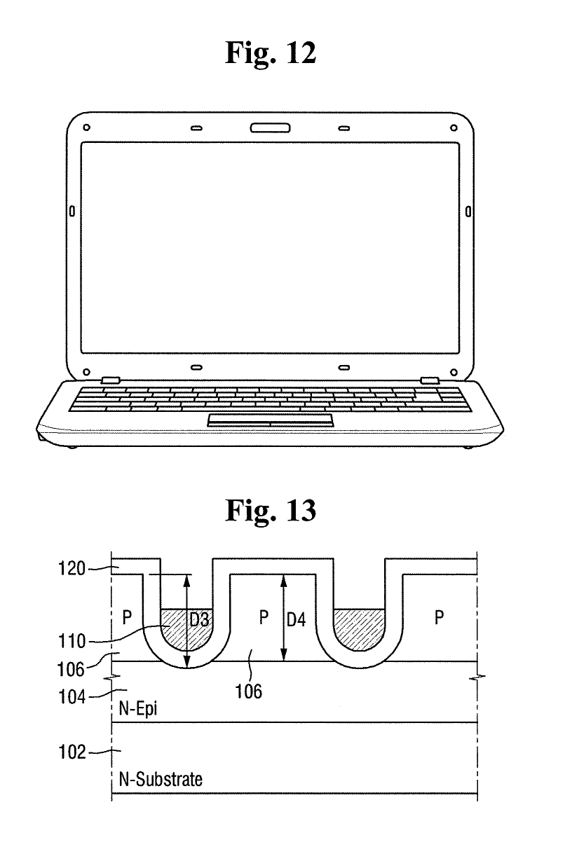

FIGS. 11 and 12 illustrate exemplary views of a semiconductor system to which the semiconductor device according to some embodiments can be applied. FIG. 11 illustrates a tablet PC, and FIG. 12 illustrates a notebook PC. It is apparent to those of skilled in the art that the semiconductor device according to some embodiments can be applied even to other integrated circuit devices that have not been exemplified.

Hereinafter, referring to FIGS. 13 to 17 and 2, a method for fabricating a semiconductor device according to the first embodiment will be described. FIGS. 13 to 17 are views of intermediate steps explaining a method for fabricating a semiconductor device according to the first embodiment.

First, referring to FIG. 13, the epi-layer 104 is formed on, e.g., directly on, the base substrate 102. Then, the body region 106 is formed, e.g., by implanting first conduction type impurities in the epi-layer 104. In other words, as illustrated in FIG. 13, the first conduction type impurities in an upper portion of the epi-layer 104 define the body region 106 on a lower portion of the epi-layer 104, so an upper surface of the body region 106 is an upper surface of the epi-layer 104, i.e., of the upper portion of the epi-layer 104.

Then, the trench 109 is formed in the substrates 102 and 104. For example, as illustrated in FIG. 13, the trench 109 may be formed in the epi-layer 104 to penetrate through the entire body region 106 and through a portion of the lower portion of the epi-layer 104. Here, the third depth D3 from the upper surface of the substrates 102 and 104, e.g., from the upper surface of the epi-payer 104, to the bottom surface of the trench 109 may be longer than the fourth depth D4 from the upper surface of the substrates 102 and 104, e.g., from the upper surface of the epi-layer 104, to a lower surface of the body region 106. It is preferable that the difference (D3−D4) is implemented to be equal to or larger than 0 and equal to or smaller than 0.5 μm. If it is assumed that the ratio between the third depth D3 and the fourth depth D4 is expressed as “p=D3/D4”, the ratio may be about 1<p≦1.5.

Then, the gate insulating film 120 may be formed along the upper surface of the substrates 102 and 104, e.g., along the upper surface of the epi-layer 104, and along the side wall and the bottom surface of the trench 109. Then, the gate 110 is formed so that the trench 109 is not fully filled with the gate 110, i.e., only a part of the trench 109 is filled with the gate 110. The gate 110 may be formed, e.g., using polysilicon, but is not limited thereto.

Referring to FIG. 14, a first preliminary source 112a is formed by implanting 310 second conduction type impurities in the vertical direction, i.e., without tilting.

Referring to FIG. 15, a second preliminary source 112b is formed by implanting 320 the second conduction type impurities at an angle tilted to the left. The implantation is performed using the recessed gate 110 without using a separate mask.

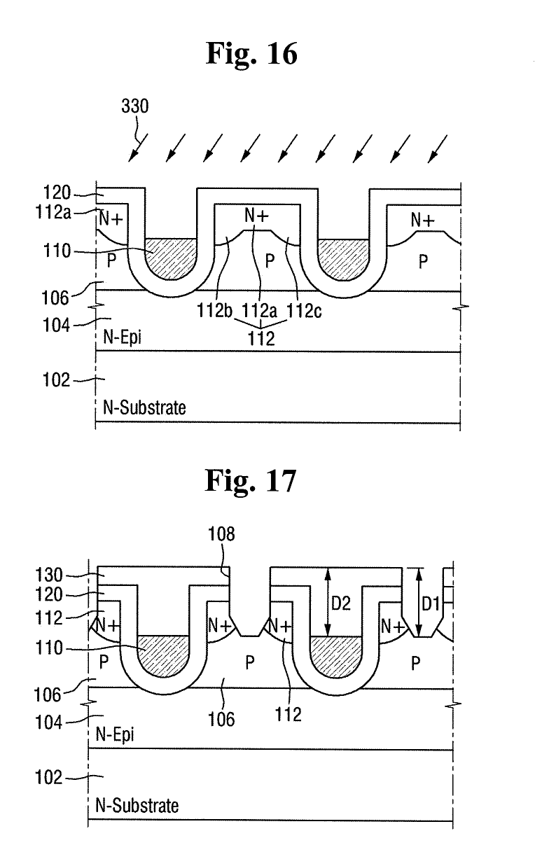

Referring to FIG. 16, a third preliminary source 112c is formed by implanting 330 the second conduction type impurities at an angle tilted to the right. The implantation is performed using the recessed gate 110 without using a separate mask.

Through three implantation stages 310, 320, and 330, the tilted source 112 is completed. The remaining processing conditions, e.g., impurity concentration, energy, and the like, of the three implantation stages 310, 320, and 330, except for the tilted angle, may be the same, but are not limited thereto.

Referring to FIG. 17, the interlayer insulating film 130 is formed on the overall surface of the substrates 102 and 104, e.g., on the upper surface of the epi-layer 104. Specifically, the interlayer insulating film 130 may be formed on the substrates 102 and 104 to fill the trench 109 therewith, and may be formed on the gate insulating film 120 formed on the surface of the substrates 102 and 104. The interlayer insulating film 130 may be formed using a material having superior gap-filling ability. The interlayer insulating film 130 may be, but is not limited to, a silicon oxide film.

Then, the surface of the interlayer insulating film 130 is planarized. For example, CMP (Chemical Mechanical Polishing) may be used.

Then, the contact hole 108 is formed in a region between adjacent trenches 109. The contact hole 108 is formed to penetrate parts of the interlayer insulating film 130, the gate insulating film 120, and the substrates 102 and 104, e.g., penetrate an upper portion of the epi-layer 104 including the body region 106. Here, the first depth D1, i.e., a distance from an upper surface of the interlayer insulating film 130 to a bottom surface of the contact hole 108, may be equal to or larger than the second depth D2, i.e., a distance from the upper surface of the interlayer insulating film 130 to an upper surface of the gate 110.

Further, the contact hole 108 may include the bottom surface, a side wall, and a tilted surface connecting the bottom surface and the side wall to each other. Here, the angle of the tilted surface may be equal to or larger than 80 degrees and smaller than 90 degrees.

Referring again to FIG. 2, the high-concentration body region 116 is formed below the contact hole 108 without using a separate mask. As described above, since the first depth D1 and the second depth D2 are equal to each other, there is no unwanted second conduction type (N type) impurity region between the high-concentration body region 116 and the body region 106. That is, a NPN parasitic transistor may not be formed.

Then, the source metal 140 is formed on the interlayer insulating film 130, and the drain metal 150 is formed on the backside of the substrates 102 and 104, e.g., on a bottom surface of the substrate 102.

Here, although only the method for fabricating a semiconductor device according to the first embodiment has been described, those skilled in the art will appreciate a method for fabricating a semiconductor device according to the second to fourth embodiments through the method according to the first embodiment.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a trench in a substrate;
a gate filling a part of the trench;
a tilted source on a side wall of the trench, the tilted source partially overlapping the gate;
an interlayer insulating film on the substrate and filling the trench; and
a contact hole penetrating parts of the interlayer insulating film and the substrate and contacting the tilted source, the contact hole having a tilted surface at an angle that is equal to or larger than 80 degrees and smaller than 90 degrees.

2. The semiconductor device as claimed in claim 1, wherein a first depth from an upper surface of the interlayer insulating film to a bottom surface of the contact hole is equal to or larger than a second depth from the upper surface of the interlayer insulating film to an upper surface of the gate.

3. The semiconductor device as claimed in claim 1, wherein an upper surface of the interlayer insulating film is planarized.

4. The semiconductor device as claimed in claim 1, further comprising a gate insulating film along an upper surface of the substrate and along a side wall and a bottom surface of the trench, the contact hole penetrating parts of the interlayer insulating film, the gate insulating film, and the substrate.

5. The semiconductor device as claimed in claim 1, further comprising a first conduction type body region in the substrate adjacent the gate, the tilted source being in the body region and of a second conduction type that is different from the first conduction type.

6. The semiconductor device as claimed in claim 5, further comprising a high-concentration body region of the first conduction type in the body region and in contact with a bottom surface of the contact hole.

7. The semiconductor device as claimed in claim 6, wherein the tilted source is in contact with the tilted surface of the contact hole and is spaced apart from the high-concentration body region.

8. The semiconductor device as claimed in claim 5, wherein a third depth from an upper surface of the substrate to a bottom surface of the trench is equal to or larger than a fourth depth from the upper surface of the substrate to a bottom of the body region.

9. The semiconductor device as claimed in claim 8, wherein a difference between the third depth and the fourth depth is equal to or larger than about 0 and is equal to or smaller than about 0.5 μm.

10. The semiconductor device as claimed in claim 8, wherein a ratio between the third depth and the fourth depth is equal to or larger than about 1 and equal to or smaller than about 1.5.

11. The semiconductor device as claimed in claim 5, wherein the substrate is of the second conduction type, the substrate including an impurity pillar of the first conduction type in the substrate along a vertical direction below the body region.

12. A semiconductor device, comprising:
a trench in a substrate;
a gate insulating film along an upper surface of the substrate and along a side wall and a bottom surface of the trench;
a gate on the gate insulating film and filling a part of the trench;
a tilted source on a side wall of the trench, the tilted source partially overlapping the gate;
an interlayer insulating film on the substrate and filling the trench; and
a contact hole penetrating parts of the interlayer insulating film, the gate insulating film, and the substrate, the contact hole being in contact with the tilted source and having a tilted surface at an angle that is equal to or larger than 80 degrees and smaller than 90 degrees,
wherein a first depth from an upper surface of the interlayer insulating film to a bottom surface of the contact hole is equal to or longer than a second depth from the upper surface of the interlayer insulating film to an upper surface of the gate.

13. The semiconductor device as claimed in claim 12, wherein the upper surface of the interlayer insulating film is planarized.

14. The semiconductor device as claimed in claim 12, further comprising a first conduction type body region in the substrate adjacent to the gate, the tilted source being in the body region and is of a second conduction type that is different from the first conduction type.

15. The semiconductor device as claimed in claim 14, further comprising a high-concentration body region of the first conduction type in the body region and in contact with a bottom surface of the contact hole.

16. A semiconductor device, comprising:
a trench in a substrate;
a gate filling a part of the trench;
a tilted source on a side wall of the trench, a bottom of the tilted source overlapping a portion of the gate and being non parallel with respect to a bottom of the substrate;
an interlayer insulating film on the substrate and filling the trench; and
a contact hole penetrating parts of the interlayer insulating film and the substrate and contacting the tilted source, the contact hole having a tilted surface at an angle that is equal to or larger than 80 degrees and smaller than 90 degrees.

17. The semiconductor device as claimed in claim 16, wherein a first depth from an upper surface of the interlayer insulating film to a bottom surface of the contact hole is equal to or larger than a second depth from the upper surface of the interlayer insulating film to an upper surface of the gate.

18. The semiconductor device as claimed in claim 17, wherein the first depth equals the second depth.

19. The semiconductor device as claimed in claim 17, wherein a third depth from an upper surface of the substrate to a bottom surface of the trench is equal to or larger than a fourth depth from the upper surface of the substrate to a bottom of the body region.

20. The semiconductor device as claimed in claim 16, wherein the entire bottom of the tilted source is non parallel with respect to the bottom of the substrate, the bottom of the tilted source extending from the tilted surface of the contact hole to the sidewall of the trench.
